(19) United States
(12) Patent Application Publication
(10) Pub. No.: US 2026/0215181 A1
(43) Pub. Date: Jul. 23, 2026

(54) SUBSTRATE STRESS MANAGEMENT USING HIGH TEMPERATURE IMPLANTATION

(71) Applicant: Applied Materials, Inc., Santa Clara, CA (US)

(72) Inventors: Olga Kucher, San Jose, CA (US); Adaeze Osonkie, Beverly, MA (US); Wonjae Lee, Fremont, CA (US); Stanislav S. Todorov, Topsfield, MA (US); Morgan Evans, Santa Clara, CA (US); Ramkumar Karur Shanmugam, Cupertino, CA (US); Pradeep Subrahmanyan, Cupertino, CA (US)

(73) Assignee: Applied Materials, Inc., Santa Clara, CA (US)

(21) Appl. No.: 19/035,245

(22) Filed: Jan. 23, 2025

(51) Int. Cl. H01L 21/02

(52) U.S. Cl. CPC H10P 14/6524; H10P 14/6539; H10P 14/69433

(57) ABSTRACT

A method for stress management in a substrate. The method may include providing a stress compensation layer on a main surface of the substrate, and performing a high-temperature implant procedure in an ion implanter to implant a dose of ions into the stress compensation layer. The high temperature implant procedure may include heating the substrate to an implant temperature, the implant temperature being between 300° C. and 750° C., and exposing the substrate to an ion beam while the substrate is held at the implant temperature, wherein the implant procedure alters an out-of-plane distortion of the substrate.

### FIELD

The present embodiments relate to stress control in substrates, and more particularly to the use of stress compensation layers to control out-of-plane distortion in substrates.

### BACKGROUND

Devices such as integrated circuits, memory devices, and logic devices may be fabricated on a substrate such as a semiconductor wafer by a combination of deposition processes, patterning, etching, ion implantation, annealing, and other processes. Often, complete fabrication of devices and related circuitry may entail many hundreds of operations, including dozens of lithographic patterning operations. In particular, lithographic operations may require that a given mask to pattern structures in a given region or level is to be aligned to preexisting structures.

A problem during fabrication of substrates is the development of out-of-plane distortion (OPD) caused by stresses within the wafer, which distortion may be referred to as warpage. This OPD may be a result of stress that develops within the wafer as a result of processing. For example, a constant stress in a film stack on a wafer (substrate) will lead to a paraboloid shape of the wafer. This paraboloid shape can pose challenges to handling the wafer during downstream processing, but has minimal effect on device overlay. However, patterning of these film stacks results in variations of the stress across the wafer, and leads to OPD shapes that are more complicated than a simple paraboloid. One can subtract the best-fit paraboloid of the OPD to obtain what are called OPD residuals. Management of these OPD residuals may be critical to achieve proper overlay between structures fabricated at different levels of a device. For example, a type of OPD often encountered is a saddle shaped wafer curvature that may develop at many instances of processing due to stress buildup in the wafer as a result of processing operations.

One approach to managing wafer (substrate) stress is to provide a stress compensation layer on the back or front side of a substrate, which layer may be used to manage stress in a substrate, such as to alter stress, and in particular may be used to provide a layer that can be used to counteract existing stress within the substrate and thus reduce OPD. In particular implementations, ion implantation into the stress compensation layer alters the stress state locally in the stress compensation layer and thus changes the stress and OPD of the substrate. In some approaches, the amount of ions implanted into different regions of a substrate may be varied to account for or to create local stress differences across the plane of the wafer.

However, while ion implantation may alter the stress state in a substrate at a given instance during processing, the substrate may subsequently be subject to additional processing operations before device fabrication on the substrate is complete. These additional processing operations may involve subjecting the substrate to further thermal treatment, where the further thermal treatment may further alter the substrate stress.

With respect to these and other considerations the present embodiments are provided.

### BRIEF SUMMARY

In various embodiments, methods for stress management in a substrate are provided. In one embodiment, a method may include providing a stress compensation layer on a main surface of the substrate, and performing a high-temperature implant procedure in an ion implanter to implant a dose of ions into the stress compensation layer. The high temperature implant procedure may include heating the substrate to an implant temperature, the implant temperature being between 300° C. and 750° C., and exposing the substrate to an ion beam while the substrate is held at the implant temperature, wherein the high-temperature implant procedure alters an out-of-plane distortion of the substrate.

In another embodiment, a method may include providing a stress compensation layer on a main surface of a substrate, wherein the substrate, with the stress compensation layer in place, exhibits an out-of-plane distortion having a first value. The method may also include performing a high temperature implant procedure to implant a dose of ions into the stress compensation layer. The high temperature implant procedure may include heating the substrate to an implant temperature, the implant temperature being above 300° C.; and exposing the substrate to an ion beam while the substrate is held at the implant temperature, wherein the high-temperature implant procedure reduces the out-of-plane distortion of the substrate from a first value to a second value.

### BRIEF DESCRIPTION OF THE DRAWING

FIG. 1A depicts an ion implanter in accordance with embodiments of the present disclosure;

FIG. 1B depicts an exemplary processing system in accordance with other embodiments of the disclosure;

FIGS. 2A-2D depict exemplary operations for OPD control according to some embodiments;

FIGS. 2E-2G depict exemplary operations for OPD control according to other embodiments;

FIG. 3A depicts a substrate system used for a series of experiments conducted for OPD control;

FIG. 3B presents a summary of OPD control using ion implantation for several implant conditions based upon the system of FIG. 3A;

FIG. 4 is a composite illustration that presents a graph depicting relaxation that is induced in a substrate by post-implantation thermal treatment for several implant conditions, and the geometry of the substrate before and after post-implantation thermal treatment; and

FIG. 5 depicts an exemplary process flow.

### DETAILED DESCRIPTION

The present embodiments will now be described more fully hereinafter with reference to the accompanying drawings, where some embodiments are shown. The subject matter of the present disclosure may be embodied in many different forms and are not to be construed as limited to the embodiments set forth herein. Instead, these embodiments are provided so this disclosure will be thorough and complete, and will fully convey the scope of the subject matter to those skilled in the art. In the drawings, like numbers refer to like elements throughout.

The embodiments described herein relate to techniques and apparatus for improved substrate stress management. The present embodiments involve a novel set of implants into a layer provided on a substrate in order to improve stress relief in the substrate. In particular, a set of high temperature implants may be performed using a beamline ion implanter to optimize the distribution of damage in the implanted layer in a manner to more effectively treat substrate stress.

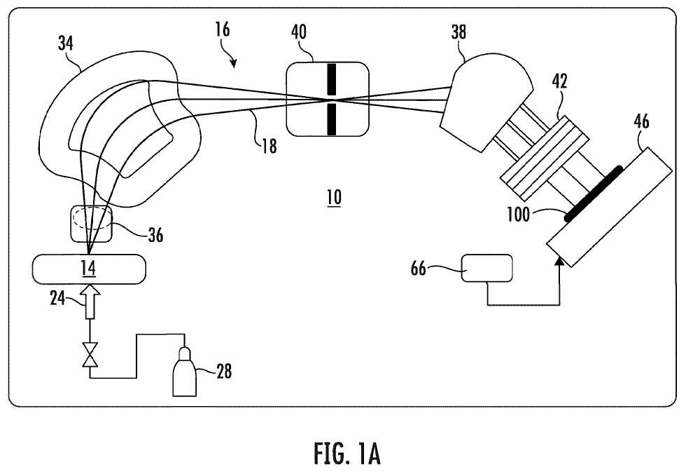

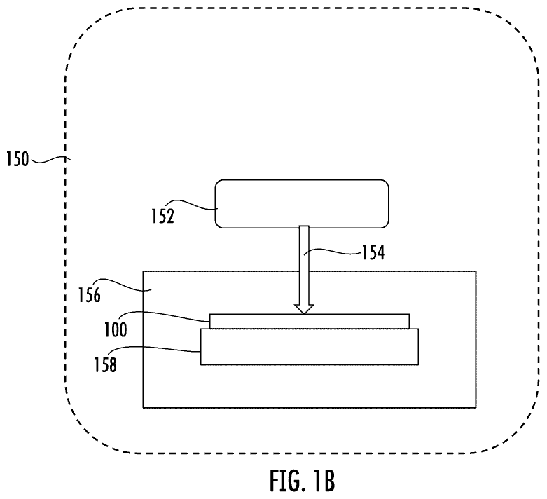

Referring now to FIG. 1A, an exemplary system in accordance with the present disclosure is shown. The ion implantation system (hereinafter “system”) 10 represents a process chamber containing, among other components, an ion source 14 for producing an ion beam 18 and a series of beam-line components 16. The ion source 14 may comprise a chamber for receiving a flow of gas 24 and generating ions therein. The ion source 14 may also comprise a power source and an extraction electrode assembly disposed near the chamber. The beam-line components 16 may include, for example, a mass analyzer 34, a first acceleration or deceleration stage 36, a collimator 38, a mass resolving slit 40, and other suitable downstream beamline components such as an energy filter 42, to accelerate the ion beam 18, decelerate the ion beam 18, shape the ion beam 18, scan the ion beam 18, and so forth.

In particular embodiments, the beam-line components 16 may filter, focus, accelerate, decelerate, and otherwise manipulate ions or the ion beam 18 to have a desired species, shape, energy, and other qualities. The ion beam 18 passing through the beam-line components 16 may be directed toward a substrate 100 mounted on a substrate stage 46 or clamped within a process chamber. As appreciated, the substrate may be moved using a control mechanism 66 in one or more dimensions (e.g., translate, rotate, and tilt). As shown, there may be one or more feed sources 28 operable with the chamber of the ion source 14. In one embodiment, the substrate stage 46 includes a heating stage capable to heat the substrate 100 to elevated temperature.

In some embodiments, the ion implantation system 10 may include a scanner (not shown), to scan the ion beam 18. For example, the ion beam 18 may be provided as a pencil beam or spot beam that is scanned with the X-Y plane of the Cartesian coordinate system. For example, a scan generator (not separately shown) may deliver a scan signal, such as an oscillating voltage, to a pair of electrode plates that generate an oscillating electric field at a scan frequency in the kHz range, such as 1 kHz, 2 kHz, 5 kHz, according to some non-limiting embodiments.

In various embodiments, different species may be used as the ions to be used to process the stress in the film. Non-limiting examples of suitable ions include silicon (Si), boron (B), carbon (C), oxygen (O), germanium (Ge), phosphorus (P), arsenic (As), nitrogen ions, and so forth as to control substrate stress.

Although non-limiting, the ion source 14 may include a power generator, plasma exciter, plasma chamber, and the plasma itself. The plasma source may be an inductively-coupled plasma (ICP) source, toroidal coupled plasma source (TCP), capacitively coupled plasma (CCP) source, helicon source, electron cyclotron resonance (ECR) source, indirectly heated cathode (IHC) source, glow discharge source, electron beam generated ion source, or other plasma sources known to those skilled in the art.

The ion source 14 may generate the ion beam 18 for processing a substrate 100. In various embodiments, the ion beam (in cross-section) may have a targeted shape, such as a spot beam or ribbon beam, as known in the art. In the Cartesian coordinate system shown, the direction of propagation of the ion beam 18 may be represented as parallel to the Z-axis, while the actual trajectories of ions with the ion beam 18 may vary. In order to process the substrate, the ion beam 18 may be accelerated to acquire a target energy by establishing a voltage (potential) difference between the ion source 14 and the wafer (substrate).

Referring now to FIG. 1B, an exemplary system in accordance with the present disclosure is shown. The processing system 150 may include an ion source 152 to generate an ion beam 154 that is directed to the substrate 100.

For example, the ion source 152 may include a power generator, plasma exciter, plasma chamber, and the plasma itself. The plasma source may be an inductively-coupled plasma (ICP) source, toroidal coupled plasma source (TCP), capacitively coupled plasma (CCP) source, helicon source, electron cyclotron resonance (ECR) source, indirectly heated cathode (IHC) source, glow discharge source, electron beam generated ion source, or other plasma sources known to those skilled in the art.

In some embodiments, the processing system may include a separate component, such as a processing chamber 156, to house the substrate 100. The processing system 150 may include a substrate stage 158 that supports the substrate 100. The substrate 100 may be heated by any suitable means, including resistive heating, radiative heating, inductive heating, and so forth. The substrate 100 may be heated either indirectly, via heating of the substrate stage 158, directly, such as by radiation or other means, or a combination of direct heating and indirect heating via the substrate stage. According to different non-limiting embodiments, the substrate 100 may be heated to elevated temperature, such as 200° C., 300° C., 400° C., 500° C., 600° C., and so forth. The processing system 150 may include any suitable known means to impart a targeted ion energy into the ion beam 18.

In some configurations, the ion source 152 may be a remote ion source that is remote from the processing chamber 156. In other configurations, the ion source 152 may be disposed as a chamber that is adjacent to and communicatively coupled to the process chamber 156, such as a compact ion beam system. For example, an extraction system (not shown) may be disposed at the boundary between the ion source 152 and processing chamber 156, in order to define, extract, and accelerate the ion beam 154 to the substrate 100. In further configurations, the ion source 152 may be incorporated within the processing chamber 156. In these further configurations, the ion source 152 generates a plasma within the processing chamber 156, and the ion beam 154 is instead a flux of ions that is extracted from the plasma within the processing chamber 156 and accelerated to the substrate 100 at a targeted ion energy, such as in known plasma deposition (PLAD) systems.

In various embodiments detailed herein a processing system or ion implanter, such as a beamline ion implanter, is used to perform a high temperature implant into a stress compensation layer on a substrate, where parameter(s) such as the ion energy or dose may be selected to adjust the OPD in a substrate. In particular embodiments, as detailed herein, the combination of ion dose and substrate temperature, as well as ion energy, is selected to impart a change in stress state and OPD that is resistant to subsequent thermal relaxation. In some embodiments, high temperature implants may be performed where ion energy and/or ion dose are varied across a substrate being implanted to selectively and/or locally alter stress in a stress compensation layer. For example, the high temperature implant may induce a locally-varying stress modification in the stress compensation layer.

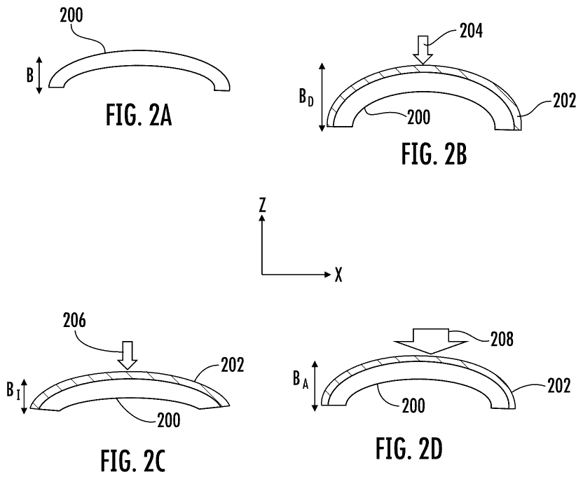

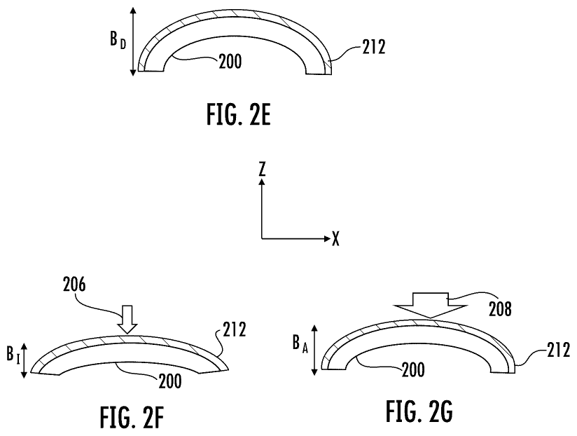

FIGS. 2A-2D illustrate an example process sequence for modifying OPD in a substrate. Turning to FIG. 2A there is shown an example of an OPD state in a substrate. For simplicity of illustration, the substrate 200 is shown as having a simple curvature, such as a parabolic curvature, leading to an OPD having a certain value along the Z-axis of the Cartesian coordinate system shown, represented by the value B. The OPD may be a result of prior processing of the substrate 200, if any. In one example, the OPD may result from device fabrication on a semiconductor wafer, represented by the substrate 200. Such processing may impart global stresses, as well as local stresses across the substrate 200 that impart global out-of plane distortions and/or local distortions, where these distortions are represented by the curved form of the substrate 200.

Turning to FIG. 2B, there is shown a subsequent instance where a layer, referred to herein as a stress compensation layer 202, has been formed on a main surface of the substrate 200. The stress compensation layer 202 may be formed by deposition of a species 204, such as by physical vapor deposition, or chemical vapor deposition (CVD) in accordance with some embodiments. In particular embodiments, the stress compensation layer 202 may be formed by CVD at elevated substrate temperature, such as 100° C., 200° C., 300° C., 400° C. and so forth. One non-limiting example of a suitable stress compensation layer for deposition on semiconductor substrates, such as silicon, is silicon nitride, referred to herein also as SiN. After deposition of stress compensation layer 202, the value of the OPD of substrate 200 may differ from the initial value, and is shown as BD.

In some embodiments, the deposition conditions of the stress compensation layer 202 may be selected so as to impart a targeted value of stress. For example, the composition of and deposition temperature for stress compensation layer 202 may be selected to impart a given amount of stress. In some examples, the stress compensation layer 202 may be deposited in a state of compressive stress that generates a convex curvature to substrate 200, while in other examples, the stress compensation layer 202 may be deposited in a state of tensile stress that generates a concave curvature to substrate 200.

Turning to FIG. 2C, there is shown a subsequent stage of processing where a high temperature implant is performed using ions 206 to implant a species into the stress compensation layer 202. The ions 206 may be provided, for example, in a beamline ion implanter, a compact ion beam processing system, a PLAD system, or other suitable system. The ion energy and ion dose of ions 206 may be selected to implant in a manner that alters the stress state in stress compensation layer 202, and accordingly changes the value of the substrate OPD, which change is shown by the after-implant OPD, labeled as BI. One result of this process may be to decrease the value of OPD of the substrate 200, so that the substrate 200 exhibits a relatively flatter main surface. Note that the ion dose and ion energy of ions 206 may be provided in a uniform manner across the substrate 200 to globally vary the stress in the stress compensation layer 202. In other embodiments, the ion dose, the ion energy, or a combination of the two may be varied across the substrate 200 to locally alter the stress in stress compensation layer 202.

In some embodiments, as discussed further below, the ion dose, ion energy, and substrate temperature for the high temperature implant of FIG. 2C may be selected so that the stress state of the stress compensation layer is better retained after subsequent processing, including exposure to high temperature processing, which processing may be characterized by a post-implantation thermal budget.

Turning to FIG. 2D there is shown a subsequent instance of processing after the substrate 200 has been subjected to further processing that exposes the substrate 200 to a thermal budget, represented by heat treatment 208. At this instance, the value of OPD is presented by B_{A}, which value may increase with respect to B_{I} because of the effect of the thermal treatment on the stress compensation layer 202.

Thus, the final stress state and OPD of a substrate, using ion implantation to control substrate OPD, may depend on the stress compensation layer, the nature of the ion implantation process, as well as post-implantation processing.

FIGS. 2E-2G depict exemplary operations for OPD control according to other embodiments. Turning to FIG. 2E, there is shown a substrate 200 having a dual function layer 212 deposited thereon. The dual function layer 212 represents a layer that is generated during processing of the substrate 200, such as during device fabrication, where the dual function layer 212 may also serve as a stress compensation layer. For example, the dual function layer 212 may have been formed as a mask layer, etch stop layer, etc., that is then suitable to act as a stress compensation layer. At FIG. 2F and FIG. 2G, the operations proceed generally as in FIG. 2C and FIG. 2D, respectively. Thus, the dual function layer 212 is subject to a high temperature implant using ions 206, and heat treatment 208.

The present inventors have discovered that final stress state and OPD in a substrate may be more effectively controlled by using a combination of high substrate temperature in conjunction with ion implantation at a suitable ion dose into a stress compensation layer.

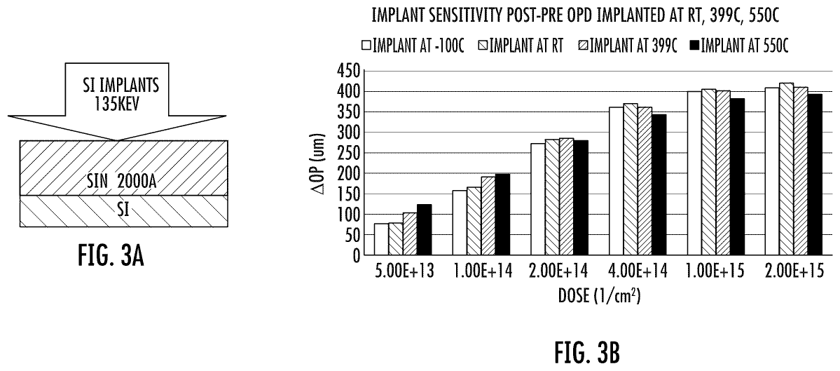

In one set of experiments, a stress compensation layer was formed on a silicon wafer, as shown in FIG. 3A. In particular, a 200 nm thick SiN layer was deposited by chemical vapor deposition as a blanket layer over a set of silicon substrates. Subsequently a series of implants were performed, where a given implant was performed on a given silicon wafer. Each implant was performed using 135 keV Si⁺ ions that were directed to the SiN layer. The implant dose of Si⁺ ions as well as the implant temperature were varied among the different wafers. A total of 6 different implant doses were used, with a total of 4 different substrate temperatures, for a total of 24 different implants into 24 different wafers, respectively.

FIG. 3B presents a summary of the results. As shown in FIG. 3B, the different substrate temperatures used for the set of experiments were −100 C, Room temperature (RT), 399° C., and 500° C. The ion doses employed were 5E13 cm⁻²; 1E14 cm⁻²; 2E14 cm⁻²; 4E14cm⁻2; 1E15 cm⁻² and 2E15 cm⁻². In particular, before implantation, as suggested in the image of FIG. 3, the wafers had the structure of a blanket layer of SiN deposited over a surface of the wafer. During implantation, a given dose of silicon ions was implanted substantially into the SiN layer. While not shown explicitly in the image, after deposition of the SiN layer and before implantation, the Si wafers exhibited an OPD of approximately 400 μm (this value is representative of B_{D} as defined in FIG. 2B). The graph of FIG. 3B plots the change in the measured OPD (ΔOPD) between the OPD before implantation (as represented by B_{D} in FIG. 2B) and the measured OPD after implantation (as represented by BI in FIG. 2C), for the various different implant conditions that were performed. Thus, ΔOPD is equivalent to B_{D}−B_{I} as defined in FIG. 2B and FIG. 2C. Thus, a relatively larger value of ΔOPD corresponds to a relatively greater reduction in OPD from the initial value 400 μm. Several features are noteworthy, as evidenced by the data. At relatively lower ion doses, as ion dose increases, the value of ΔOPD increases, meaning the wafers become relatively flatter. Beyond ion doses of 1E15 cm⁻² the effect on ΔOPD plateaus. Additionally, at relatively lower ion doses up to 2E14 cm⁻² the value of ΔOPD increases with increasing substrate temperature. This effect reverses at higher ion doses, where, at least above RT, the value of ΔOPD decreases with increasing substrate temperature, while the relative differences in ΔOPD with temperature are not as pronounced as at lower ion doses. For example, at low ion doses ≤1e14 cm⁻² the high-temperature implants (399° C. and 500° C.) induce substantially greater values of ΔOPD (25-35%) compared to implants performed at RT or −100° C. (19%).

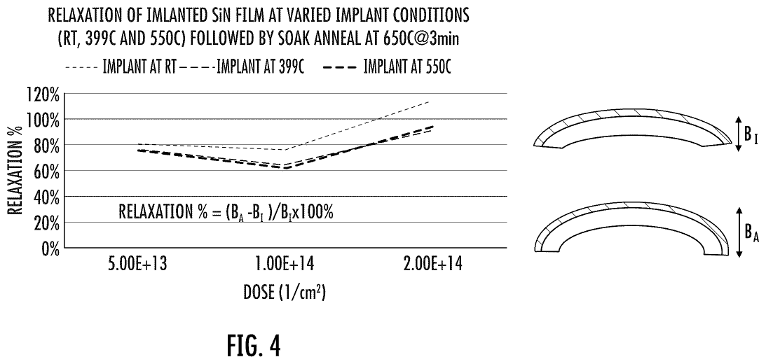

Turning to FIG. 4, there is shown a graph that depicts the relaxation after post-implantation annealing of a substrate with an implanted stress compensation layer. The relaxation is plotted as a function of ion dose and implant temperature during the ion implantation operation. In FIG. 4, the relaxation %=(B_{A}−B_{I})/B_{I}×100%, where B_{A} and B_{I} are defined previously, and shown in FIG. 2C and FIG. 2D. Thus, a value of relaxation % above zero indicates that the OPD of the substrate has increased with respect to the OPD after implantation, as a result of the post-implantation thermal processing. FIG. 4 shows data for ion doses up to 1e14 cm⁻² and for implant temperatures of RT or above. The post-implantation annealing condition for all samples is a 650° C. soak anneal for 3 min. As shown, the substrates exhibit a relaxation after post-implantation annealing for all the implant conditions. Note that relaxation is relatively greater for wafers that received RT implantation, as opposed to wafers that received high temperature implantation (399° C. or 500° C.), for all implant doses. Moreover, the difference in relaxation between substrates implanted at 399° C. and 500° C. is minimal. In addition, the difference in relaxation between wafers implanted at room temperature and wafers implanted at high temperature is more pronounced as ion implantation dose increases from 5E13 cm⁻² to 1E14 cm⁻² to 2E14 cm⁻2

Without being bound by any theory, the above results may be explained in the following manner. During ion implantation, the ion bombardment of the stress-compensation layer creates atomic collision cascades, which cascades facilitate the relocation of target atoms into energetically more stable positions, thus lowering the existing wafer stress. In general, this phenomenon takes place at all target implantation temperatures, although the amount of stress relief does vary with implant temperature. By performing the implantation at an elevated substrate temperature—say, several hundred ° C.—the duration of favorable conditions is extended for relocating target atoms to find lower-stress locations.

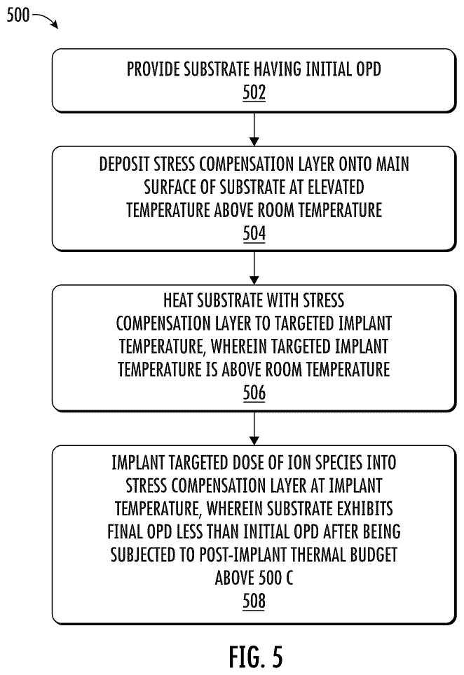

Turning to FIG. 5 there is shown a process flow 500 according to embodiments of the disclosure. At block 502, a substrate, such as a silicon wafer, is provided, having an initial value of OPD.

At block 504, a stress compensation layer is deposited on a main surface of the substrate. In some examples, the stress compensation layer may be deposited on the substrate at any suitable stage of processing. In some embodiments, the processing of the substrate to form semiconductor devices, for example, may take place on a second main surface, opposite the main surface that receives the stress compensation layer. In other embodiments the stress compensation layer may be on the same main surface on which surface the semiconductor devices are formed.

In some embodiments, the stress compensation layer may be a silicon oxide or a silicon nitride layer. In some embodiments, the stress compensation layer may be deposited by CVD at an elevated temperature, such as 300° C. or 400° C.

At block 506, the substrate is heated to a targeted implant temperature above room temperature, such as 399° C., or 550° C.

At block 508, the stress compensation layer is implanted with a targeted ion dose of a given ion species at the implant temperature. As such, the implant conditions are arranged so that the substrate exhibits a final OPD that is less than the initial OPD, after the substrate is subjected to a post-implantation thermal budget. In some examples., the post-implantation thermal budget may be at 500° C. or greater.

Advantages provided by the present embodiments are multifold. In one advantage, the alterations to the substrate stress that are made via the high temperature implant into the stress compensation layer continue through future thermal processing, meaning that the alterations in stress are more resistant to change that may be introduced by subsequent processing at high temperature. As another advantage, the stress alteration enables improved overlay and wafer handling in future lithography and other process steps that take place subsequent to the high temperature implantation.

The present disclosure is not to be limited in scope by the specific embodiments described herein. Indeed, other various embodiments and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, the present disclosure has been described herein in the context of a particular implementation in a particular environment for a particular purpose, yet those of ordinary skill in the art will recognize the usefulness is not limited thereto and the present disclosure may be beneficially implemented in any number of environments for any number of purposes. Thus, the claims set forth below are to be construed in view of the full breadth and spirit of the present disclosure as described herein.

What is claimed is:

1. A method of stress management in a substrate, comprising:
providing a stress compensation layer on a main surface of the substrate;
performing a high-temperature implant procedure in an ion implanter to implant a dose of ions into the stress compensation layer, the high-temperature implant procedure comprising:
heating the substrate to an implant temperature, the implant temperature being between 300° C. and 750° C.; and
exposing the substrate to an ion beam while the substrate is held at the implant temperature, wherein the high-temperature implant procedure alters an out-of-plane distortion of the substrate.

2. The method of claim 1, wherein the stress compensation layer has a compressive stress before ion implantation.

3. The method of claim 1 wherein the high-temperature implant procedure reduces an out-of-plane distortion of the substrate by at least 25%.

4. The method of claim 3, wherein the high-temperature implant procedure reduces the out-of-plane distortion of the substrate by up to 100%.

5. The method of claim 4, wherein a final value of the out-of-plane distortion of the substrate after subjecting the substrate to a post-implantation thermal process is less than an initial value of the out-of-plane distortion by 10% to 100%.

6. The method of claim 1, wherein the stress compensation layer is a silicon nitride layer, and wherein the dose of ions comprise silicon ions or nitrogen ions.

7. The method of claim 1, wherein the stress compensation layer comprises a silicon nitride layer, that is deposited at a deposition temperature, the deposition temperature being between 300° C. to 500° C., and wherein the substrate comprises a silicon base that is disposed subjacent to the stress compensation layer.

8. The method of claim 1, wherein the substrate comprises a 300 mm Si wafer, and wherein the high-temperature implant procedure comprises a dose of ions that is effective to reduce a global OPD by at least 100 mm.

9. The method of claim 8, wherein the high-temperature implant procedure comprises a dose of silicon ions in a range of 1E13/cm² to 2E15/cm², wherein an ion energy of the silicon ions is between 100 keV and 300 keV.

10. The method of claim 1, wherein the high-temperature implant procedure comprises varying an implant dose across the substrate to create locally varying stress modification in the stress compensation layer.

11. A method of stress management in a substrate, comprising:
providing a stress compensation layer on a main surface of the substrate, wherein the substrate, with the stress compensation layer in place, exhibits an out-of-plane distortion having a first value; and
performing a high-temperature implant procedure to implant a dose of ions into the stress compensation layer, the high-temperature implant procedure comprising:
heating the substrate to an implant temperature, the implant temperature being above 300° C.; and
exposing the substrate to an ion beam while the substrate is held at the implant temperature, wherein the a high-temperature implant procedure reduces the out-of-plane distortion of the substrate from a first value to a second value.

12. The method of claim 11, wherein the stress compensation layer has a compressive stress before ion implantation.

13. The method of claim 11 wherein the a high-temperature implant procedure reduces an out-of-plane distortion of the substrate by at least 25%.

14. The method of claim 13, wherein the a high-temperature implant procedure reduces the out-of-plane distortion of the substrate by up to 100%.

15. The method of claim 14, wherein a final value of the out-of-plane distortion of the substrate after subjecting the substrate to a post-implantation thermal process is less than an initial value of the out-of-plane distortion by 10% to 100%.

16. The method of claim 11, wherein the stress compensation layer is a silicon nitride layer, and wherein the ion beam comprises silicon ions or nitrogen ions.

17. The method of claim 11, wherein the stress compensation layer comprises a silicon nitride layer that is deposited at a deposition temperature, the deposition temperature being between 300° C. to 500° C., and wherein the substrate comprises a silicon base that is disposed subjacent to the stress compensation layer.

18. The method of claim 11, wherein the substrate comprises a 300 mm Si wafer, and wherein the high-temperature implant procedure comprises a dose of ions that is effective to reduce a global OPD by at least 100 μm.

19. The method of claim 18, wherein the high-temperature implant procedure comprises a dose of silicon ions in a range of 1E13/cm² to 2E15/cm², wherein an ion energy of the silicon ions is between 100 keV and 300 keV.

20. The method of claim 11, wherein the high-temperature implant procedure comprises varying an implant dose across the substrate to create locally varying stress modification in the stress compensation layer.
